(19) United States
(12) Patent Application Publication
(10) Pub. No.: US 2023/0229091 A1
(43) Pub. Date: Jul. 20, 2023

(54) ADAPTIVE OPTICAL ELEMENT FOR MICROLITHOGRAPHY

(71) Applicant: Carl Zeiss SMT GmbH, Oberkochen (DE)

(72) Inventors: Matthias Manger, Aalen-Unterkochen (DE); Markus Raab, Schillingsfuerst (DE)

(21) Appl. No.: 18/188,814

(22) Filed: Mar. 23, 2023

Related U.S. Application Data
(63) Continuation of application No. PCT/EP2021/077485, filed on Oct. 6, 2021.

(30) Foreign Application Priority Data
Oct. 8, 2020 (DE) 102020212743.3

(51) Int. Cl. G03F 7/00; G01K 7/16; G02B 26/08

(52) U.S. Cl. CPC G03F 7/70266; G01K 7/16; G02B 26/0825; G03F 7/70025; G03F 7/70033; G03F 7/70883

(57) ABSTRACT

An adaptive optical element for microlithography comprises at least one manipulator for changing the shape of an optical surface of the optical element. The manipulator comprises a dielectric medium which is deformable via an electric field, work electrodes for generating the electric field in the dielectric medium, and a measuring electrode for measuring temperature. The measuring electrode is arranged in a direct assemblage with the dielectric medium. The measuring electrode has a temperature-dependent resistance.

### CROSS-REFERENCE TO RELATED APPLICATIONS

The present application is a continuation of, and claims benefit under 35 USC 120 to, international application PCT/EP2021/077485, filed Oct. 6, 2021, which claims benefit under 35 USC 119 of German Application No. 10 2020 212 743.3, filed Oct. 8, 2020. The entire disclosure of these applications are incorporated by reference herein.

### FIELD

The disclosure relates to an adaptive optical element for microlithography, comprising at least one manipulator for changing the shape of an optical surface of the optical element, and a microlithographic projection exposure apparatus comprising at least one such adaptive optical element.

### BACKGROUND

A projection lens with wavefront aberrations that are as small as possible is often desired to help make imaging of the mask structures on the wafer as precisely as possible. Therefore, projection lenses are often equipped with manipulators, which render it possible to correct wavefront errors by changing the state of individual optical elements of the projection lens. Examples of such a change in state comprise a change of relative position in one or more of the six rigid-body degrees of freedom of the relevant optical element and a deformation of the optical element. For the purposes of the latter change in state, the optical element is embodied, in general, in the form of the aforementioned adaptive optical element. The latter can comprise piezoelectric or electrostrictive manipulators for the purposes of actuating the optical surface. The functionality of such manipulators is generally based on the deformation of a dielectric medium by the application of an electric field. To determine the desired change in state, the aberration characteristic of the projection lens is usually measured regularly and, if appropriate, changes in the aberration characteristic between the individual measurements are determined by simulation. In this regard, for example, lens element heating effects can be taken into account computationally.

When using piezoelectric or electrostrictive adaptive optical elements, temperature variations in the actuator material can lead to significant inaccuracies in the surface shape corrections carried out by the adaptive optical element.

### SUMMARY

The disclosure seeks to provide an adaptive optical element of the type set forth at the outset which solves the aforementioned problems and, for example, allows a surface shape correction of the adaptive optical element to be implemented with improved accuracy.

By way of example, the disclosure provides an adaptive optical element for microlithography, comprising at least one manipulator for changing the shape of an optical surface of the optical element, the manipulator comprising: a dielectric medium, which is deformable via an electric field, work electrodes for generating the electric field in the dielectric medium, and a measuring electrode which serves for measuring temperature, is arranged in a direct assemblage with the dielectric medium, and has a temperature-dependent resistance.

An arrangement of the measuring electrode in a direct assemblage with the dielectric medium should be understood to mean that the measuring electrode and the dielectric medium directly adjoin one another. This means that no further medium, such as an adhesive layer, is arranged between the measuring electrode and the dielectric medium. For example, the measuring electrode can be embedded in the dielectric medium so that it is completely surrounded by the dielectric medium. Alternatively, the measuring electrode can also be arranged on a surface of the dielectric medium.

For example, the measuring electrode can be made of a noble metal, for example configured as a platinum electrode. Examples of suitable platinum electrodes are PT100 and PT1000. For example, the adaptive optical element comprises an evaluation device for converting the resistance value measured at the measuring electrode into a temperature value.

The arrangement of the measuring electrode in a direct assemblage with the dielectric medium can help lead to a relatively precise measurement of the temperature of the dielectric medium, in any case at least of the temperature in a region of the dielectric medium adjoining the measuring electrode. Such a precise temperature measurement may not be possible in the case of an arrangement that does not take place in a direct assemblage, for instance in the case where the measuring electrode is adhesively bonded thereon. The result of measuring the temperature of the dielectric medium can be taken into account or used when controlling the manipulator, for the purposes of correcting the temperature. The length expansion of the manipulator can thus be controlled more accurately, as a result of which the surface shape of the adaptive optical element can in turn be corrected with improved accuracy.

According to an embodiment, the measuring electrode is arranged in a direct assemblage with the dielectric medium over at least an area of 1 mm², for example at least 5 mm² or at least 10 mm².

According to a further embodiment, the measuring electrode is surrounded by the dielectric medium on at least two sides in the direct assemblage. For example, the measuring electrode is surrounded by the dielectric medium in the direction of the electric field generated by the work electrodes, that is to say on the sides of the measuring electrode which extend transversely to the electric field. According to a further embodiment, the measuring electrode is completely embedded in the dielectric medium, that is to say surrounded by the dielectric medium on all sides with the exception of feed lines.

According to a further embodiment, the measuring electrode is printed onto a surface of the dielectric medium.

According to a further embodiment, the measuring electrode is line-shaped with a multiplicity of bends. For example, the measuring electrode can be designed in the form of a wire which has a multiplicity of bends. For example, the bends are formed in such a way that the measuring electrode has a meandering shape.

According to a further embodiment, the measuring electrode has a flat shape with a length-to-width ratio of at least 2:1, for example at least 3:1, at least 5:1 or at least 10:1. The flat shape can be rectangular, oval or configured in some other way in this case.

According to a further embodiment, the work electrodes are arranged in the form of a stack of at least three electrodes and the measuring electrode is arranged outside of the stack. In other words, the measuring electrode is arranged outside of an active volume of the dielectric medium, in which a length expansion occurs during manipulator operation. According to an alternative embodiment, the measuring electrode is arranged between two work electrodes, that is to say within the stack of work electrodes.

According to a further embodiment, the dielectric medium is integrally formed. An integral dielectric medium is understood to mean a contiguous and seamless monolithic dielectric medium, that is to say possibly present connections between various volume portions of the dielectric medium are seamless. By way of example, a seamless connection is understood to mean a connection that was generated by sintering but not a connection generated by adhesive bonding. That is to say, individual volume regions of the dielectric medium cannot be separated from one another without altering or destroying the material structure in the separation region.

According to a further embodiment, the adaptive optical element furthermore comprises an electrical circuit, using which the electrical resistance of the measuring electrode is measurable. An electrical circuit should be understood to mean the combination of electrical or electromechanical individual elements, such as a power source, resistors and measuring equipment, etc. However, not all of the aforementioned individual elements need be contained in the electrical circuit; for example, other individual electrical elements can also be used. For example, the electrical circuit may comprise a two-wire circuit or a four-wire circuit for measuring the resistance at the measuring electrode.

According to a further embodiment, the electrical circuit is further configured to measure an impedance between the measuring electrode and one of the work electrodes. For example, the impedance is measured between the measuring electrode and a grounded work electrode. This can be the work electrode closest to the measuring electrode. For example, at least a capacitive resistance between the measuring electrode and the work electrode is measured via the impedance measurement. The capacitive resistance corresponds to the imaginary part of the impedance.

According to a further embodiment, the electrical circuit comprises at least one switch for switching between the resistance measurement and the impedance measurement.

According to a further embodiment, the electrical circuit comprises a frequency-controllable AC voltage source, which is connected in such a way that the resistance measurement is performable using a low AC voltage frequency and the impedance measurement is performable using a high AC voltage frequency.

According to a further embodiment, provision is made of an evaluation device which serves to determine a strain state of the dielectric medium, which is arranged in the region of the measuring electrode, from a dependence of the impedance on the amplitude of an AC voltage applied to the measuring electrode for the impedance measurement. For example, the strain state is determined from the capacitive resistance ascertained via the impedance measurement.

According to a further embodiment, the adaptive optical element comprises a plurality of manipulators of the aforementioned type, each with a measuring electrode, with the measuring electrodes being connected in series to a direct current source. For example, a voltmeter is connected to each of the measuring electrodes for the purposes of measuring the voltage drop across them. In this way, the number of wirings or cables used for measuring the resistance at the measuring electrodes can be reduced.

According to a further embodiment, the optical surface is configured to reflect EUV radiation. According to a further embodiment, the optical surface is configured to reflect DUV radiation, for example a wavelength of approximately 365 nm, approximately 248 nm, or approximately 193 nm.

Furthermore, the disclosure provides a microlithographic projection exposure apparatus comprising at least one adaptive optical element according to any one of the above-described embodiments or embodiment variants is provided. For example, the adaptive optical element is part of a projection lens of the projection exposure apparatus.

The above-described and other features of the embodiments according to the disclosure will be explained in the description of the figures and in the claims. The individual features can be implemented, either separately or in combination, as embodiments of the disclosure. Furthermore, they can describe embodiments which are independently protectable and protection for which is claimed only during or after pendency of the application, as the case may be.

### BRIEF DESCRIPTION OF THE DRAWINGS

The above and further features of the disclosure will be illustrated in the following detailed description of exemplary embodiments according to the disclosure with reference to the accompanying schematic drawings. In the drawings:

FIG. 1 shows an embodiment of a microlithographic projection exposure apparatus comprising an adaptive optical element;

FIG. 2 shows an embodiment of an adaptive optical element in an initial state and in a corrected state;

FIG. 3 shows an embodiment of an adaptive optical element in an initial state and in a corrected state;

FIG. 4 shows a diagram which for a manipulator of an adaptive optical element illustrates a strain S as a function of an applied electric field E for different temperatures ϑ;

FIG. 5 shows a diagram which for a manipulator of the adaptive optical element illustrates a strain S as a function of the temperature ϑ;

FIG. 6 shows an embodiment of a manipulator of an adaptive optical element according to FIG. 2 or FIG. 3, comprising a measuring electrode and an electrical circuit connected thereto;

FIG. 7 shows a sectional view of the measuring electrode according to FIG. 6 along the line A-A′ in three different embodiments;

FIG. 8 shows an embodiment of a manipulator of an adaptive optical element according to FIG. 2 or FIG. 3, comprising a measuring electrode and an electrical circuit connected thereto;

FIG. 9 shows a further embodiment of a manipulator of an adaptive optical element according to FIG. 2 or FIG. 3, comprising a measuring electrode and an electrical circuit connected thereto;

FIG. 10 shows an embodiment of a manipulator of an adaptive optical element according to FIG. 2 or FIG. 3, comprising a measuring electrode and an electrical circuit connected thereto;

FIG. 11 shows an embodiment of an adaptive optical element according to FIG. 2 or FIG. 3, comprising a plurality of manipulators arranged in series and an electrical circuit connected to the manipulators; and

FIG. 12 shows an embodiment of a microlithographic projection exposure apparatus comprising an adaptive optical element.

### DETAILED DESCRIPTION OF EXEMPLARY EMBODIMENTS

In the exemplary embodiments or embodiments or embodiment variants described below, elements which are functionally or structurally similar to one another are provided with the same or similar reference signs as far as possible. Therefore, for understanding the features of the individual elements of a specific exemplary embodiment, reference should be made to the description of other exemplary embodiments or the general description of the disclosure.

In order to facilitate the description, a Cartesian xyz-coordinate system is indicated in the drawing, from which system the respective positional relationship of the components illustrated in the figures is evident. In FIG. 1, the y-direction runs perpendicularly to the plane of the drawing into the plane, the x-direction runs toward the right, and the z-direction runs upward.

FIG. 1 shows an embodiment according to the disclosure of a microlithographic projection exposure apparatus 10. The present embodiment is designed for operation in the EUV wavelength range, that is to say with electromagnetic radiation having a wavelength of less than 100 nm, for example a wavelength of approximately 13.5 nm or approximately 6.8 nm. All optical elements are embodied as mirrors as a result of this operating wavelength. However, the disclosure is not restricted to projection exposure apparatuses in the EUV wavelength range. Further embodiments according to the disclosure are designed, for example, for operating wavelengths in the UV range, such as, for example, 365 nm, 248 nm or 193 nm. In this case, at least some of the optical elements are configured as conventional transmission lens elements. A projection exposure apparatus configured for operation in the DUV wavelength range is described below with reference to FIG. 12.

The projection exposure apparatus 10 in accordance with FIG. 1 comprises an exposure radiation source 12 for generating exposure radiation 14. In the present case, the exposure radiation source 12 is embodied as an EUV source and it can comprise, for example, a plasma radiation source. The exposure radiation 14 first passes through an illumination optical unit 16 and is steered to a photomask 18 by the latter.

The photomask 18 has mask structures to be imaged on a substrate 24 and it is displaceably mounted on a mask displacement stage 20. The substrate 24 is displaceably mounted on a substrate displacement stage 26. As depicted in FIG. 1, the photomask 18 can be embodied as a reflection mask or, alternatively, it can also be configured as a transmission mask, for example for UV lithography. In the embodiment according to FIG. 1, the exposure radiation 14 is reflected at the photomask 18 and thereupon passes through a projection lens 22 configured to image the mask structures onto the substrate 24. The substrate 24 is displaceably mounted on a substrate displacement stage 26. The projection exposure apparatus 10 can be designed as a so-called scanner or a so-called stepper. The exposure radiation 14 is guided within the illumination optical unit 16 and the projection lens 22 via a multiplicity of optical elements, presently in the form of mirrors.

In the illustrated embodiment, the illumination optical unit 16 comprises four optical elements 30-1, 30-2, 30-3 and 30-4 in the form of reflective optical elements or mirrors. The projection lens 22 likewise comprises four optical elements 30-5, 30-6, 30-7 and 30-8, which are likewise in the form of reflective elements or mirrors. The optical elements 30-1 to 30-8 are arranged in an exposure beam path 28 of the projection exposure apparatus 10 for the purposes of guiding the exposure radiation 14.

In the embodiment shown, the optical element 30-5 is configured as an adaptive optical element which has an active optical surface 32 in the form of its mirror surface, the shape of which can be actively changed for the purposes of correcting local shape defects. In further embodiments, a different optical element or a plurality of the optical elements 30-1, 30-2, 30-3, 30-4, 30-5, 30-6, 30-7 and 30-8 can also each be configured as an adaptive optical element.

Furthermore, one or more of the optical elements 30-1, 30-2, 30-3, 30-4, 30-5, 30-6, 30-7 and 30-8 of the projection exposure apparatus 10 can be movably mounted. To this end, a respective rigid body manipulator is assigned to each of the movably mounted optical elements. By way of example, the rigid body manipulators each enable a tilt and/or a displacement of the assigned optical elements substantially parallel to the plane in which the respective reflective surface of the optical elements lies. Hence, the position of one or more of the optical elements can be changed for the purposes of correcting imaging aberrations of the projection exposure apparatus 10.

According to one embodiment, the projection exposure apparatus 10 comprises a control device 40 for generating control signals 42 for the manipulation units provided, such as the aforementioned rigid body manipulators, of one or more adaptive optical elements and/or possibly further manipulators. In FIG. 1, the transmission of a control signal 42 to the adaptive optical element 30-5 is illustrated in exemplary fashion. According to an embodiment for correcting aberrations of the projection lens 22, the control device 40 ascertains the control signals 42 on the basis of wavefront deviations 46 of the projection lens 22, measured via a wavefront measuring device 44, via a feedforward control algorithm.

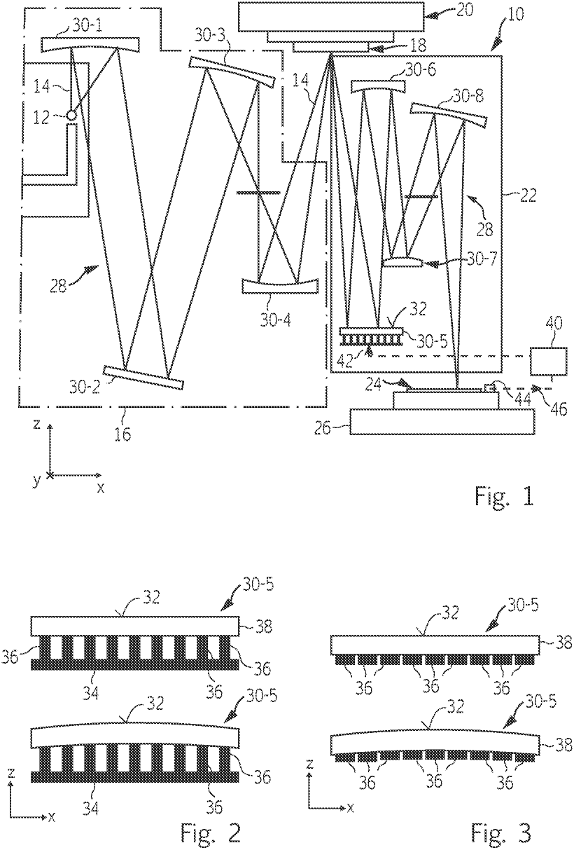

A first embodiment of the adaptive optical element 30-5 is illustrated in FIG. 2. The illustration in the upper section of FIG. 2 shows the adaptive optical element 30-5 in an initial state, in which the shape of the optical surface 32 has an initial shape, a plane shape in this case. The illustration in the lower section of FIG. 2 shows the adaptive optical element 30-5 in a corrected state, in which the shape of the optical surface 32 has a changed shape, a convexly arched shape in this case.

The adaptive optical element 30-5 comprises a support element 34 in the form of a back plate and a mirror element 38, the surface of which forms the active optical surface 32 and serves to reflect the exposure radiation 14. A multiplicity of manipulators 36, which are also referred to as actuators, are arranged along the bottom of the mirror element 38. Here, these can be positioned both in the x-direction and in the y-direction, that is to say in a two-dimensional arrangement, along the bottom of the mirror element 38. The manipulators 36, only a few of which have been provided with a reference sign in FIG. 2 for reasons of clarity, connect the support element 34 to the mirror element 38. The manipulators 36 are configured to change their extent along their longitudinal direction in the case of actuation. In the embodiment according to FIG. 2, the manipulators 36 are actuatable across or perpendicular to the optical surface 32. The manipulators are each driven individually and can therefore be actuated independently of one another.

In the corrected state shown in the lower section of FIG. 2, centrally arranged manipulators 36 have an increased length on account of their actuation, and so the convexly arched shape arises for the optical surface 32.

FIG. 3 illustrates a further embodiment of the adaptive optical element 30-5. In a manner analogous to FIG. 2, the illustration in the upper section of FIG. 3 shows the adaptive optical element 30-5 in an initial state, in which the shape of the optical surface 32 has a plane shape as initial shape. The illustration in the lower section of FIG. 3 shows the adaptive optical element 30-5 in a corrected state, in which the shape of the optical surface 32 has a convexly arched and hence a changed shape.

The adaptive optical element 30-5 according to FIG. 3 differs from the embodiment according to FIG. 2 to the extent that the manipulators 36 are arranged on the bottom of the mirror element 38 not transverse but parallel to the optical surface 32 and the manipulators 36 are not carried by a rigid support element arranged parallel to the mirror element 38. That is to say, the manipulators 36 are deformable not transverse to the optical surface 32, as in FIG. 2, but parallel to the optical surface 32. These manipulators 36 are therefore also referred to as transverse manipulators. As a result of the strain or contraction of the individual manipulators 36 parallel to the surface, a bending moment is introduced into the mirror element 38, leading to deformation of the latter, as illustrated in the lower section of FIG. 3.

By driving each individual manipulator 36, it is possible both in the embodiment according to FIG. 2 and in the embodiment according to FIG. 3 to set profiles of the mirror element 38 in a targeted fashion and consequently correct the optical system, for example the projection lens 22 or the illumination optical unit 16, of the projection exposure apparatus 10 to the best possible extent.

According to an embodiment variant of the adaptive optical element 30-5 according to FIG. 3 but not shown in the drawing, the manipulators 36 configured as transverse manipulators are embedded in one or more monolithic tiles.

The manipulators 36 of the adaptive optical element 30-5 each comprise a dielectric medium 48 (see FIG. 6, for example) which is deformable by application of an electric field. This can be a piezoelectric material or an electrostrictive material. The deformation is based on the piezoelectric effect in the case of a piezoelectric material, while it is based on the electrostrictive effect in the case of an electrostrictive material. In this text, the electrostrictive effect is understood to mean the component of a deformation of a dielectric medium based on an applied electric field, in which the deformation is independent of the direction of the applied field and, for example, proportional to the square of the electric field. In contrast thereto, the linear response of the deformation to the electric field is referred to as piezoelectric effect.

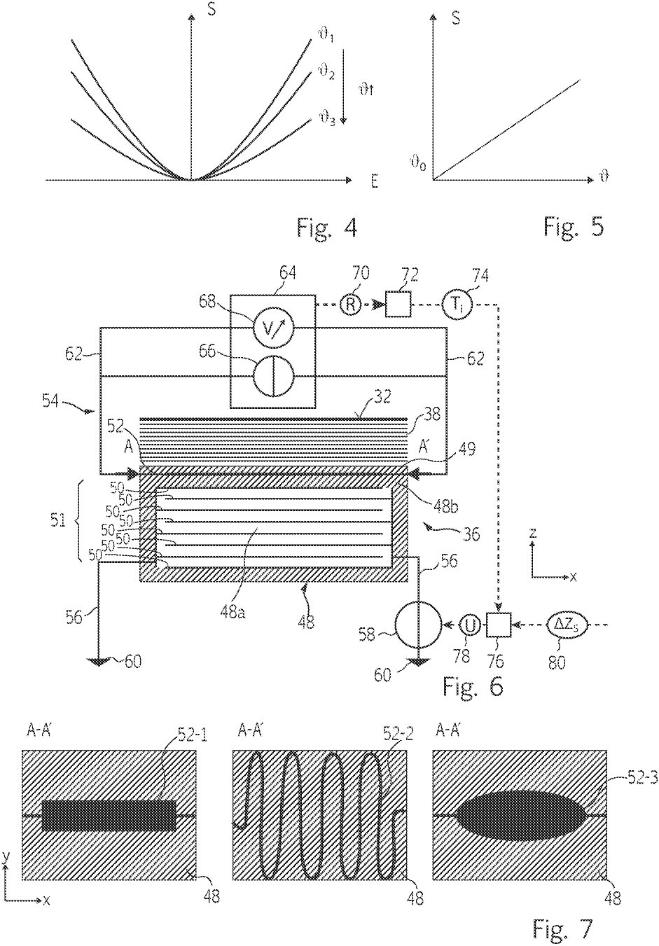

However, the strain S of the manipulators 36 or actuators as a function of the electric field E applied is very temperature-dependent. This effect is illustrated in FIG. 4 on the basis of a schematic S-E diagram of a manipulator 36 manufactured using electrostrictive material, for different temperatures ϑ (ϑ₃ > ϑ₂ > ϑ₁).

As illustrated in FIG. 5, the dielectric medium moreover significantly expands when the temperature ϑ changes in relation to the nominal temperature ϑ₀ on account of the coefficient of thermal expansion (CTE) of the medium.

FIG. 6 illustrates a first embodiment of a manipulator 36 contained in the adaptive optical element 30-5 according to FIG. 2 or FIG. 3. This manipulator 36 comprises the aforementioned dielectric medium 48, which bears against the back side of the mirror element 38, work electrodes 50, a measuring electrode 52, an electrical circuit 54 connected to the measuring electrode 52, and a voltage source 58 with an adjustable voltage value connected to the work electrodes 50 via a wiring 56. The dielectric medium 48 is integrally formed as a ceramic part, with the work electrodes 50 being embedded or integrated therein. The integral dielectric medium 48 is a contiguous and seamless monolithic dielectric medium and is generated by sintering, for example.

Expressed differently, the work electrodes 50 are arranged in an assemblage with the integral dielectric medium 48. The work electrodes 50 are contained in the dielectric medium 48 in the form of an electrode stack 51. In the embodiment shown, the electrode stack 51 contains eight plate-shaped work electrodes 50 arranged one above the other. The whole area of the dielectric medium 48 arranged between electrodes 50 is referred to as the active volume 48a of the dielectric medium 48. The active volume 48a is shown as a white area in FIG. 6. The area of the dielectric medium 48 arranged outside of the electrode stack is cross-hatched in FIG. 6 and is correspondingly referred to as the inactive volume 48b. In the embodiment shown, the inactive volume 48b completely surrounds the active volume 48a.

The wiring 56 of the work electrodes 50 alternately connects these to an electrical ground 60 and to one pole of the adjustable voltage source 58, the other pole of the voltage source likewise being connected to ground 60. The electric field generated between two adjacent work electrodes 50 in each case thus likewise alternates. Since the dielectric medium 48 is an electrostrictive material in the present case, the expansion of the dielectric medium 48 caused by the electric field is independent of the direction of the electric field, that is to say the change in the expansion in the z-direction of the layers of the dielectric medium 48 arranged between the electrodes 50 is directed in the same way. Hence, the length expansion Δz of the active volume 48a of the dielectric medium 48 changes in the z-direction when a control voltage U generated by the voltage source 58 is applied. The absolute value of the change in the length expansion depends on the control voltage generated by the voltage source 58; according to an embodiment, this value is proportional to the value of the control voltage.

The measuring electrode 52 serves to measure the temperature and in the present case is made of platinum, for example PT100 or PT1000, as a result of which the measuring electrode 52 has an electrical resistance that is highly temperature-dependent. The measuring electrode 52 is arranged in the dielectric medium 48 and is embedded in the dielectric medium 48 in the inactive volume 48b, specifically between the mirror element 38 and the uppermost work electrode 50, with the result that the measuring electrode is surrounded by the dielectric medium 48 at least from above and below, that is to say from two sides, and is even completely surrounded in the present case. For example, the measuring electrode can be arranged in the center of the inactive volume 48b. In any case, the measuring electrode 52 is thus arranged in a direct assemblage with the dielectric medium 48. This should be understood to mean that the measuring electrode 52 and the dielectric medium 48 directly adjoin one another. In an alternative embodiment of the arrangement of the measuring electrode 52 in the direct assemblage with the dielectric medium 48, the measuring electrode 52 can also be printed onto the surface 49 of the dielectric medium 48 adjoining the mirror element 38.

As is apparent from FIG. 6, the measuring electrode 52 is configured to be line-shaped in a sectional view, that is to say in the x-z plane. FIG. 7 shows three different embodiments 52-1, 52-2, and 52-3 of the measuring electrode 52 in a plan view, that is to say in the x-y plane along the section A-A′ according to FIG. 6. The measuring electrodes 52-1 and 52-3 are configured as a flat shape in the left-hand and the right-hand representation of FIG. 7, respectively. In the embodiment 52-1 shown on the left, the shape is a rectangle with a length-to-width ratio of approximately 4:1, and in the embodiment 52-3 shown on the right, it is an oval with a length-to-width ratio of approximately 2.5:1. In the embodiment 52-2 shown in the center of FIG. 7, the measuring electrode is line-shaped in the form of a wire with a multiplicity of bends. The measuring electrode 52-2 hence has a meandering shape. As a result of the wire-like design, the measuring electrode 52-2 has a comparatively high resistance, and so a current intensity used for resistance measurement can be kept as low as possible. The measuring electrodes 52-1, 52-2 and 52-3 each have an area of 1 mm² in the x-y plane, and hence they are arranged in a direct assemblage with the dielectric medium 48 over at least this area.

In the embodiment according to FIG. 6, the electrical circuit 54 to which the measuring electrode 52 is connected comprises a wiring 62 and a resistance measuring device 64. The resistance measuring device 64 comprises a direct current source 66 and a voltmeter 68 which are connected in parallel with one another at the measuring electrode 52 via the wiring 62. This wiring 62 is used to carry out a four-wire measurement of the electrical resistance R of the measuring electrode 52. In this case, a known electrical current intensity is applied to the measuring electrode 52 via the direct current source 66. The voltage drop across the measuring electrode 52 is tapped at high resistance and measured using the voltmeter 68. In this arrangement, falsification of the measurement due to line and connection resistances is avoided.

The resistance value 70 ascertained by the resistance measuring device 64 is converted into a current temperature value 74, also referred to as the actual temperature Ti, by an evaluation device 72. The actual temperature Tᵢ is then transmitted to a control unit 76 for controlling the voltage source 58 connected to the work electrodes 60. The control unit 76 is configured to specify for the adjustable voltage source 58 the current voltage value U (reference sign 78) to be generated thereby. For this purpose, a target expansion value Δzₛ (reference sign 80) of the manipulator 36 in the z-direction is transmitted to the control unit 76 as part of the control signal 42 shown in FIG. 1. In the embodiment shown, the control unit 76 when ascertaining the voltage value 78 takes into account the influence of the measured actual temperature Ti on the expansion of the dielectric medium 48 in the z-direction and accordingly adjusts the voltage value 78 transmitted to the voltage source 58. According to further embodiments, the control unit 76 can alternatively or additionally be configured to generate a control signal for a heating or cooling device, by which the temperature in the dielectric medium 48 is adjusted or kept constant.

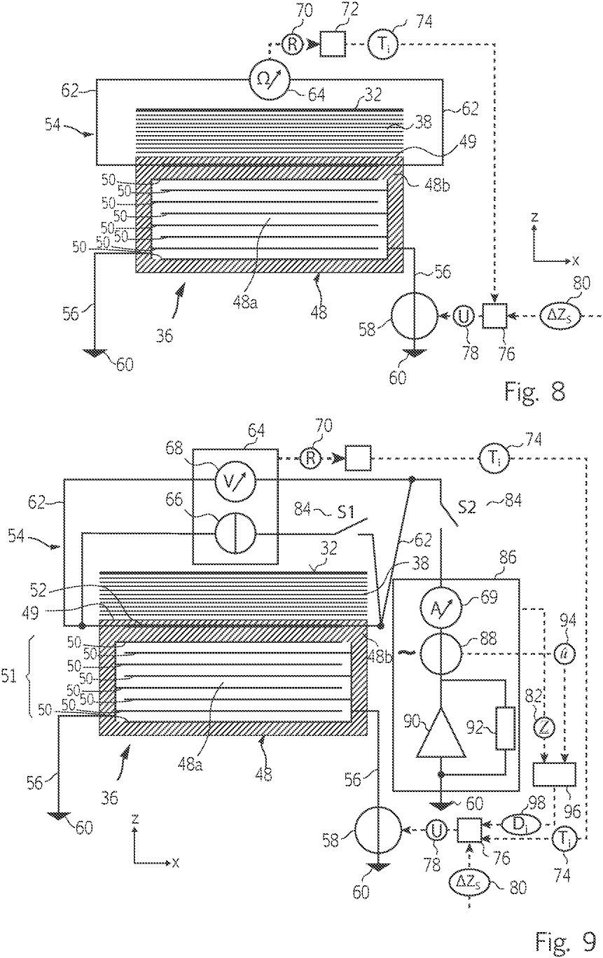

A further embodiment of a manipulator 36 according to one of FIGS. 2 and 3 is illustrated in FIG. 8. The embodiment according to FIG. 8 differs from the embodiment according to FIG. 6 only in the configuration of the electrical circuit 54 connected to the measuring electrode 52. It is designed to carry out a two-wire measurement rather than a four-wire measurement. For this purpose, the electrical circuit 54 comprises as the resistance measuring device 64 a resistance measuring device available in various embodiments. The latter is connected directly to the measuring electrode 52, usually contains a direct current source, and may further comprise a Wheatstone bridge, for example.

A further embodiment of a manipulator 36 according to one of FIGS. 2 and 3 is illustrated in FIG. 9. The embodiment according to FIG. 9 differs from the embodiment according to FIG. 6 to the effect of the electrical circuit 54 also being configured to measure a complex impedance Z (reference sign 82) between the measuring electrode 52 and the uppermost work electrode 50, that is to say the work electrode 50 immediately adjacent to the measuring electrode 52, in addition to measuring the resistance at the measuring electrode 52.

The electrical circuit 54 has two switches S1 and S2 (reference sign 84) for switching between the resistance measurement and the impedance measurement. If the switch S1 is closed and the switch S2 is open, the result is the wiring 62 of the measuring electrode 52 according to FIG. 6 for measuring the resistance. If, on the other hand, switch S1 is opened and switch S2 is closed, an impedance measuring device 86 is activated. In this switching state, the upper output of the impedance measuring device 86 is connected to the measuring electrode 52. Like the uppermost work electrode 50, the lower output of the impedance measuring device 86 is connected to the electrical ground 60.

The impedance measuring device 86 comprises an AC voltage source 88 for applying an AC voltage to the measuring electrode 52, an ammeter 69, and further electrical components such as an operational amplifier 90 and a resistor 92. The AC voltage source 88 is configured to vary the amplitude û (reference sign 94) of the generated AC voltage over time during the measurement process. The impedance measuring device 86 ascertains the impedance 82 for different amplitudes 94 on the basis of the current intensity measured by the ammeter 69 and transmits the ascertained impedance to an evaluation device 96. From the functional relationship between the amplitude 94 of the AC voltage and the capacitive resistance of the dielectric medium 48 (inactive volume 48b) between the measuring electrode 52 and the uppermost work electrode 50 that emerges from the imaginary part of the impedance 82, the evaluation device 96 ascertains a current strain state Dᵢ (reference sign 98) of the dielectric medium 48 in the inactive volume 48b. In other words, the evaluation device 96 determines the strain state 98 from the dependence of the impedance 82 on the amplitude 94.

The strain state 98 is transmitted to the control unit 76 in addition to the temperature value 74 ascertained via the resistance measuring device 64. When determining the voltage value 78, the control unit 76 also takes into account the strain state 98 in addition to the temperature value 74 already processed in the embodiment according to FIG. 6. Knowing the strain state 98 allows the control unit 76 to draw better conclusions about the currently existing manipulator expansion and thus to ascertain the voltage value 78 with better accuracy, with the result that the target expansion value 80 can be achieved with great accuracy on the basis of the voltage value 78.

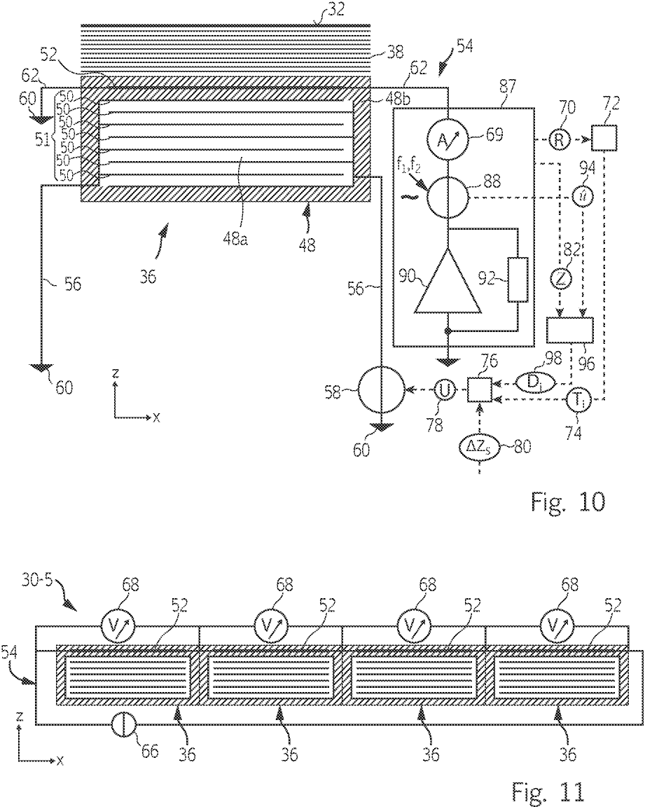

A further embodiment of a manipulator 36 according to one of FIGS. 2 and 3 is illustrated in FIG. 10. The embodiment according to FIG. 10 differs from the embodiment according to FIG. 9 to the effect of the resistance measurement and the impedance measurement being carried out in a combined resistance/impedance measuring device 87, with one end of the measuring electrode 52 being connected to the electrical ground 60 and the other end of the measuring electrode 52 being connected to the measuring device 87. The measuring device 87, like the measuring device 86 according to FIG. 9, comprises the ammeter 69, the electrical components 90 and 92 for measuring the impedance 82, and the AC voltage source 88, which is controllable in terms of frequency in the present embodiment and which can be operated at least at a low frequency f₁ and a high frequency f₂.

To ascertain the current resistance value 70, the AC voltage source 88 is operated at the low frequency f₁, which has a value of approximately 0 Hz to 100 Hz, for example. The frequency f₁ is chosen to be so low that the resistance 70 of the measuring electrode 52 can be measured by measuring the current intensity passing through the measuring electrode 52 using the ammeter 69. Like in the embodiment according to FIG. 9, the measured resistance is converted into a current temperature value 74 via the evaluation device 72 and transmitted to the control unit 76.

To ascertain the impedance 82, the AC voltage source 88 is operated at the high frequency f₂, which has a value of approximately 100 Hz to 1 MHz, for example. The value of the frequency f₂ is chosen in such a way that the complex impedance 82 between the measuring electrode 52 and the uppermost work electrode can be measured for different AC voltage amplitudes 94 in a manner analogous to the mode of operation of the impedance measuring device 86 according to FIG. 9. The respective AC voltage amplitude 94 and the impedance 82 measured therewith are transmitted to the evaluation device 96, like in the embodiment according to FIG. 9, with the evaluation device ascertaining the strain state 98 therefrom and transmitting the latter to the control unit 76.

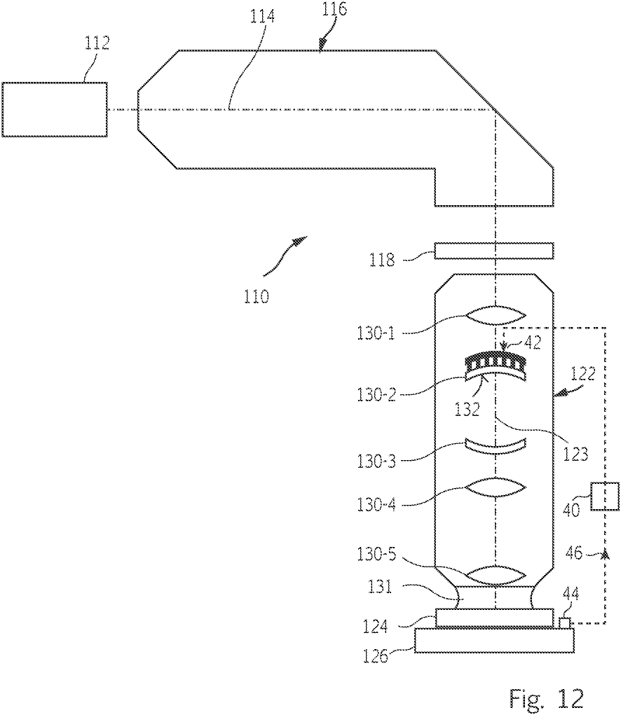

FIG. 11 illustrates an embodiment of the adaptive optical element 30-5 according to one of FIGS. 2 and 3 with a plurality of manipulators 36 arranged next to one another, that is to say in a row. To simplify the drawing, only the manipulators 36 of the corresponding adaptive optical element 30-5 are shown in FIG. 11. The electrical circuit 54 connects the measuring electrodes 52 of the manipulators in series and comprises a direct current source 66 of the type shown in FIG. 6, which is connected to the series connection of the measuring electrodes 52, for the purpose of generating the same current intensity in each of the measuring electrodes 52. Furthermore, a voltmeter 68 of the type shown in FIG. 6 is connected to each of the measuring electrodes 52 for the purpose of measuring the voltage drop across the relevant measuring electrode 52.

FIG. 12 shows a schematic view of a projection exposure apparatus 110 configured for operation in the DUV wavelength range and comprising an illumination optical unit in the form of a beam-shaping and illumination system 116 and comprising a projection lens 122. In this case, DUV stands for “deep ultraviolet” and denotes a wavelength of the exposure radiation 114 utilized by the projection exposure apparatus 110 of between 100 nm and 250 nm. The beam-shaping and illumination system 116 and the projection lens 122 can be arranged in a vacuum housing and/or be surrounded by a machine room with corresponding drive apparatuses.

The DUV projection exposure apparatus 110 comprises a DUV exposure radiation source 112. By way of example, an ArF excimer laser that emits exposure radiation 114 in the DUV range at, for example, approximately 193 nm may be provided to this end.

The beam-shaping and illumination system 116 illustrated in FIG. 12 guides the exposure radiation 114 to a photomask 118. The photomask 118 is embodied as a transmissive optical element and can be arranged outside the systems 116 and 122. The photomask 118 has a structure of which a reduced image is projected onto a substrate 124 in the form of a wafer or the like via the projection lens 122. The substrate 124 is displaceably mounted on a substrate displacement stage 126.

The projection lens 122 has a number of optical elements 130 in the form of lens elements and/or mirrors for projecting an image of the photomask 118 onto the substrate 124. In the embodiment illustrated, the optical elements 130 comprise lens elements 130-1, 130-4 and 130-5, the mirror 130-3 and the further mirror embodied as adaptive optical element 130-3. In this case, individual lens elements and/or mirrors of the projection lens 122 may be arranged symmetrically in relation to an optical axis 123 of the projection lens 122. It should be noted that the number of lens elements and mirrors of the DUV projection exposure apparatus 110 is not restricted to the number shown. More or fewer lens elements and/or mirrors may also be provided. Furthermore, the mirrors are generally curved on their front side for beam shaping.

An air gap between the last lens element 130-5 and the substrate 124 may be replaced by a liquid medium 131 which has a refractive index of > 1. The liquid medium 131 may be high-purity water, for example. Such a construction is also referred to as immersion lithography and has an increased photolithographic resolution. The medium 131 can also be referred to as an immersion liquid.

In the embodiment shown in FIG. 12, the mirror configured as adaptive optical element 130-2 is embodied to allow the shape of its mirror surface 132 to be actively changed for the purposes of correcting local shape defects. The mirror surface is therefore also referred to as active optical mirror surface 132. In this case, the adaptive optical element 130-2 is configured analogously to the adaptive optical element 30-5 described above with reference to FIGS. 1, 2, 3, and 11. All statements made above in respect of the adaptive optical element 30-5 can consequently be applied to the adaptive optical element 130-2.

In a manner analogous to the projection exposure apparatus 10 according to FIG. 1, the adaptive optical element 130-2 is controlled by control signals 42 which are ascertained by a control device 40 on the basis of wavefront deviations 46 of the projection lens 122 measured via a wavefront measuring device 44. Without loss of generality, FIG. 12 here only shows one actuator device, but it is understood that a multiplicity of actuator devices can be present, each of which is able to be controlled individually by open-loop and/or closed-loop control.

The above description of exemplary embodiments, embodiments or embodiment variants should be understood to be by way of example. The disclosure effected thereby firstly enables the person skilled in the art to understand the present disclosure and the features associated therewith, and secondly encompasses alterations and modifications of the described structures and methods that are also obvious in the understanding of the person skilled in the art. Therefore, all such alterations and modifications, insofar as they fall within the scope of the disclosure in accordance with the definition in the accompanying claims, and equivalents are intended to be covered by the protection of the claims.

List of reference signs

| | |
|---|---|
| 10 | Projection exposure apparatus |
| 12 | Exposure radiation source |
| 14 | Exposure radiation |
| 16 | Illumination optical unit |
| 18 | Photomask |
| 20 | Mask displacement stage |
| 22 | Projection lens |
| 24 | Substrate |
| 26 | Substrate displacement stage |
| 28 | Exposure beam path |
| 30-1, 30-2, 30-3, 30-4, 30-6, 30-7, 30-8 | Optical elements |
| 30-5 | Adaptive optical element |
| 32 | Active optical surface |
| 34 | Support element |
| 36 | Manipulator |
| 38 | Mirror element |
| 40 | Control device |
| 42 | Control signal |
| 44 | Wavefront measuring device |
| 46 | Wavefront deviation |
| 48 | Dielectric medium |
| 48 a | Active volume |
| 48 b | Inactive volume |
| 49 | Surface |
| 50 | Work electrode |
| 51 | Electrode stack |
| 52 | Measuring electrode |
| 54 | Electrical circuit |
| 56 | Wiring of the work electrodes |
| 58 | Adjustable voltage source of the work electrodes |
| 60 | Electrical ground |
| 62 | Wiring of the measuring electrode |
| 64 | Resistance measuring device |
| 66 | Direct current source |
| 68 | Voltmeter |
| 69 | Ammeter |
| 70 | Resistance value |
| 72 | Evaluation device |
| 74 | Temperature value |
| 76 | Control unit |
| 78 | Voltage value |
| 80 | Target expansion value |
| 82 | Impedance |
| 84 | Switch |
| 86 | Impedance measuring device |
| 87 | Combined resistance/impedance measuring device |
| 88 | AC voltage source |
| 90 | Operational amplifier |
| 92 | Resistor |
| 94 | AC voltage amplitude |
| 96 | Evaluation device |
| 98 | Strain state |
| 110 | Projection exposure apparatus |
| 112 | Exposure radiation source |
| 114 | Exposure radiation |
| 116 | Beam-shaping and illumination system |
| 118 | Photomask |
| 122 | Projection lens |
| 123 | Optical axis |
| 124 | Substrate |
| 126 | Substrate displacement stage |
| 130 | Optical element |
| 130-1, 130-5 130-4, | Lens element |
| 130-2 | Adaptive optical element |
| 130-3 | Mirror |
| 131 | Liquid medium |
| 132 | Active optical mirror surface |

What is claimed is:

1. An optical element, comprising:
a manipulator configured to change a shape of an optical surface of the optical element, the manipulator comprising:
a dielectric medium;
work electrodes configured to generate an electric field configured to deform the dielectric medium; and
a measuring electrode configured to measure a temperature of the dielectric medium, wherein:
the measuring electrode is in a direct assemblage with the dielectric medium;
the measuring electrode has a temperature-dependent resistance; and
the measuring electrode is surrounded by the dielectric medium on at least two sides in the direct assemblage.

2. The optical element of claim 1, wherein the measuring electrode is arranged in the direct assemblage with the dielectric medium over at area of at least one square millimeter.

3. The optical element of claim 1, wherein the measuring electrode is printed on a surface of the dielectric medium.

4. The optical element of claim 1, wherein the measuring electrode is line-shaped, and the measuring electrode comprises a multiplicity of bends.

5. The optical element of claim 1, wherein the measuring electrode has a flat shape with a length-to-width ratio of at least 2:1.

6. The optical element of claim 1, wherein the work electrodes are arranged in a stack comprising at least three electrodes, and the measuring electrode is arranged outside of the stack.

7. The optical element of claim 1, wherein the dielectric medium is integrally formed.

8. The optical element of claim 1, further comprising an electrical circuit configured to measure an impedance between the measuring electrode a work electrode.

9. The optical element of claim 8, further comprising an evaluation device in a region of the measuring electrode, wherein the evaluation device is configured to determine a strain state of the dielectric medium from a dependence of the impedance on an amplitude of an AC voltage applied to the measuring electrode.

10. The optical element of claim 1, further comprising an electrical circuit configured to measure an electrical resistance of the measuring electrode.

11. The optical element of claim 10, wherein the electrical circuit is configured to measure an impedance between the measuring electrode and a work electrode.

12. The optical element of claim 11, wherein the electrical circuit has at least one switch for switching between the resistance measurement and the impedance measurement.

13. The optical element of claim 11, wherein the electrical circuit comprises a frequency-controllable AC voltage source, which is connected in such a way that the resistance measurement is performable using a low AC voltage frequency and the impedance measurement is performable using a high AC voltage frequency.

14. The optical element of claim 10, comprising a plurality of manipulators,
wherein each manipulator comprises:
a dielectric medium;
work electrodes configured to generate an electric field configured to deform the dielectric medium; and
a measuring electrode configured to measure a temperature of the dielectric medium,
wherein, for each manipulator:
the measuring electrode is in a direct assemblage with the dielectric medium;
the measuring electrode has a temperature-dependent resistance; and
the measuring electrode is surrounded by the dielectric medium on at least two sides in the direct assemblage, and
wherein the measuring electrodes are connectable in series to a direct current source.

15. The optical element of claim 1, wherein the optical surface is configured to reflect EUV radiation.

16. The optical element of claim 1, wherein the optical surface is configured to reflect DUV radiation.

17. The optical element of claim 1, comprising a plurality of manipulators,
wherein each manipulator comprises:
a dielectric medium;
work electrodes configured to generate an electric field configured to deform the dielectric medium; and
a measuring electrode configured to measure a temperature of the dielectric medium,
wherein, for each manipulator:
the measuring electrode is in a direct assemblage with the dielectric medium;
the measuring electrode has a temperature-dependent resistance; and
the measuring electrode is surrounded by the dielectric medium on at least two sides in the direct assemblage, and
wherein the measuring electrodes are connectable in series to a direct current source.

18. An apparatus, comprising:
an optical element according to claim 1,
wherein the apparatus is a microlithographic projection exposure apparatus.

19. The apparatus of claim 18, wherein the apparatus is an EUV microlithographic projection exposure apparatus.

20. The apparatus of claim 18, wherein the apparatus is an DUV microlithographic projection exposure apparatus.
